(19) United States
(12) Patent Application Publication
(10) Pub. No.: US 2021/0358927 A1
(43) Pub. Date: Nov. 18, 2021

(54) Memory And Method For Forming The Same

(71) Applicant: Shanghai Huahong Grace Semiconductor Manufacturing Corporation, Pudong (CN)

(72) Inventors: Xufeng WANG, Pudong (CN); Tao YU, Pudong (CN); Binghan LI, Pudong (CN)

(73) Assignee: Shanghai Huahong Grace Semiconductor Manufacturing Corporation, Pudong (CN)

(21) Appl. No.: 17/012,391

(22) Filed: Sep. 4, 2020

(30) Foreign Application Priority Data
May 13, 2020 (CN) 202010403424.8

(51) Int. Cl. H01L 27/11517; G11C 16/08

(52) U.S. Cl. CPC H01L 27/11517; G11C 16/08

(57) ABSTRACT

The present disclosure provides a memory and a method for forming the memory. The memory includes: a substrate including an erase region and a floating gate region, wherein the floating gate region is adjacent to the erase region, and both sides of the erase region are disposed with the floating gate region; a floating gate structure disposed on the floating gate region; a control gate structure disposed on the floating gate structure; and a word line gate structure disposed on the substrate on both sides of the erase region and the floating gate region, wherein the word line gate structure is in contact with a part of the control gate structure, and a first sidewall is disposed between the floating gate structure and the word line gate structure. The memory has good performance.

### CROSS-REFERENCE TO RELATED APPLICATIONS

This application claims the benefit of priority to Chinese patent application No. 202010403424.8, filed on May 13, 2020, the entire disclosures of which are incorporated herein by reference.

### TECHNICAL FIELD

The present disclosure relates to the field of semiconductor manufacturing, and more particularly to a memory and a method for forming the memory.

### BACKGROUND

In the current semiconductor industry, integrated circuit product mainly includes three types: analog circuit, digital circuit and digital/analog hybrid circuit. In whatever types of circuits, memory is an important circuit of the digital circuit. In recent years, flash memory (referred to as flash) has developed rapidly. Flash memory features that it can keep stored information for a long time without power on, and has the advantages of high integration, fast storage speed, and easy to erase and rewrite. Therefore, it has been widely applied in many fields such as microcomputer, automatic control, etc.

Flash memory mainly includes two types: stack gate flash memory and split gate flash memory. The stacked flash memory has a floating gate and a control gate above the floating gate, whose structure may cause over erasure problem. Different from the stacked flash memory, the split gate flash memory has a word line as an erase gate disposed at one side of the floating gate, whose structure may effectively avoid over erasure problem.

However, there is still a need for improving performance of the split gate flash memory.

### SUMMARY

The present disclosure provides a memory and a method for forming the memory to improve the performance of the memory.

An embodiment of the present disclosure provides a memory, including: a substrate including an erase region and a floating gate region, wherein the floating gate region is adjacent to the erase region, and both sides of the erase region are disposed with the floating gate region; a floating gate structure disposed on the floating gate region; a control gate structure disposed on the floating gate structure; and a word line gate structure disposed on the substrate on both sides of the erase region and the floating gate region, wherein the word line gate structure is in contact with a part of the control gate structure, and a first sidewall is disposed between the floating gate structure and the word line gate structure.

In some embodiment, the memory further includes: an erase gate structure disposed on the erase region, wherein the erase gate structure is disposed between adjacent floating gate structures.

In some embodiment, the memory further includes: a source region disposed in the erase region; and a drain region disposed in the substrate on both sides of the floating gate structure, the control gate structure and the word line gate structure.

In some embodiment, the memory further includes: a second sidewall disposed on a surface of the control gate structure.

In some embodiment, the memory further includes: a third sidewall disposed on a sidewall surface of the second sidewall and a sidewall surface of the control gate structure, and a part of a top surface of the floating gate structure is exposed through the third sidewall and the control gate structure.

In some embodiment, the control gate structure includes a control gate dielectric layer and a control gate electrode layer on a surface of the control gate dielectric layer, the control gate dielectric layer includes an oxide layer, a nitride layer on the oxide layer and an oxide layer on the nitride layer, and the control gate electrode layer is made of a material including polysilicon.

In some embodiment, the floating gate structure includes a floating gate dielectric layer and a floating gate electrode layer on a surface of the floating gate dielectric layer, the floating gate dielectric layer is made of a material including silicon oxide, and the floating gate electrode layer is made of a material including polysilicon.

Another embodiment of the present disclosure provides a method for forming a memory, including: providing a substrate including an erase region and a floating gate region, wherein the floating gate region is adjacent to the erase region, and both sides of the erase region is disposed with the floating gate region; forming a floating gate material film in the erase region and in the floating gate region; forming a control gate structure on a surface of the floating gate material film in the floating gate region and exposing the floating gate material film in the erase region; etching the floating gate material film to expose a surface of the substrate so as to form a floating gate structure in the floating gate region, wherein the floating gate structure includes a sidewall having a first side and a second side opposite to each other, and the first side is adjacent to the floating gate region; forming a first sidewall on a sidewall surface of the first side of the floating gate structure; and forming a word line gate structure on a sidewall surface of the control gate structure and a sidewall surface of the first sidewall, wherein the word line gate structure is in contact with a part of the control gate structure.

In some embodiments, the method further includes: forming a mask layer on the surface of the floating gate material film after the floating gate material film is formed and before the control gate structure is formed, wherein a mask opening is disposed in the mask layer, and the surface of the floating gate material film in the erase region and in the floating gate region is exposed through the mask opening.

In some embodiments, forming the control gate structure includes: forming a control gate dielectric material film on a bottom surface and a sidewall surface of the mask opening and a top surface of the mask layer; forming a control gate electrode material film on a surface of the control gate dielectric material film; and etching the control gate dielectric film and the control gate electrode material film to expose the floating gate material film so as to form the control gate structure in the floating gate region.

In some embodiments, the method further includes: forming a second sidewall material film on a sidewall surface of the control gate electrode material film after the control gate electrode material film is formed and before the control gate dielectric material film and the control gate electrode material film are etched; etching the second sidewall material film and the control gate electrode material film to expose the control gate dielectric material film so that the second sidewall material film forms the second sidewall and the control gate material film forms a control gate electrode layer; etching the control gate dielectric material film after the control gate electrode layer and the second sidewall are formed to expose the floating gate material film and the top surface of the mask layer so as to form a control gate dielectric layer on a sidewall surface of the mask layer and on a part of the bottom surface of the mask opening.

In some embodiments, the method further includes: forming a first protective layer on an exposed top surface of the control gate electrode layer after the second sidewall and the control gate electrode layer are formed, and before the control gate dielectric material film is etched; and etching the control gate dielectric material film with the first protective layer and the second sidewall as a mask to form the control gate dielectric material film, wherein the control gate dielectric layer and the control gate electrode layer constitute the control gate structure.

In some embodiments, the method further includes: forming an erase gate structure on the erase region after the control gate structure is formed and before the word line gate structure is formed.

In some embodiments, forming the erase gate structure includes: etching the floating gate material film with the mask layer, the control gate structure and the second sidewall as a mask to expose the substrate so as to form a floating gate opening exposing a surface of the erase region in the floating gate material film; forming an erase gate material film in the mask opening and the floating gate opening, and on a surface of the second sidewall, on a surface of the control gate structure and on a surface of the mask layer; and planarizing the erase gate material film to expose the surface of the second sidewall, the surface of the control gate structure and the surface of the mask layer to form the erase gate structure, wherein the erase gate structure is disposed between adjacent control gate structures.

In some embodiments, the method further includes: forming a second protective layer on a surface of the erase gate structure after the erase gate structure is formed and before the floating gate structure is formed.

In some embodiments, the method further includes: forming a third sidewall on the surface of the control gate structure and on the surface of the second sidewall in the mask opening after the control gate structure and the second sidewall are formed and before the floating gate opening is formed; and etching the floating gate material film with the mask layer, the control gate structure, the second sidewall and the third sidewall as a mask to expose the substrate so as to form the floating gate opening.

In some embodiments, forming the third sidewall includes: forming a third sidewall material film on a sidewall surface of the control gate structure, on the surface of the second sidewall and on the surface of the mask layer in the mask opening; and etching the third sidewall material film to expose the floating gate material film, the control gate structure, the second sidewall and the top surface of the mask layer so as to form the third sidewall.

In some embodiments, the third sidewall includes a first insulation layer on a sidewall surface of the control gate structure and on a sidewall surface of the second sidewall, a second insulation layer on a surface of the first insulation layer, and a third insulation layer on a surface of the second insulation layer; wherein the method for forming the memory further includes: removing the third insulation layer in the third sidewall to expose a part of the surface of the floating gate material film after the floating gate opening is formed; and forming the erase gate structure in the floating gate opening and the mask opening after the third insulation layer is removed.

In some embodiments, the method further includes: performing an ion implantation process in the substrate exposed at a bottom of the floating gate opening to form a source region in the substrate in the erase region after the third sidewall is formed and before the erase gate structure is formed.

In some embodiments, forming the floating gate material film includes: forming a floating gate dielectric material film on the surface of the substrate; and forming a floating gate electrode material film on a surface of the floating gate dielectric film.

In some embodiments, forming the floating gate structure includes: removing the mask layer and the control gate dielectric layer on the sidewall surface of the mask layer to expose the floating gate material film; and etching the floating gate material film with the second sidewall, the control gate structure and the erase gate structure as a mask to expose the surface of the floating gate dielectric material film so that the floating gate electrode material film forms a floating gate electrode layer and the floating gate structure is formed in the floating gate region.

In some embodiments, forming the first sidewall includes: forming a first sidewall material film on a surface of the control gate structure, on a surface of the floating gate structure and on the surface of the substrate; and etching the first sidewall material film to expose the surface of the substrate and the surface of the control gate structure so as to form the first sidewall on a sidewall surface of the floating gate structure.

In some embodiments, forming the word line gate structure includes: forming a word line gate material film on the surface of the substrate, on a surface of the first sidewall and on a surface of the control gate structure; and etching back the word line gate material film to expose the surface of the substrate so as to form the word line gate structure.

In some embodiments, the method further includes: forming a drain region in the substrate on both sides of the control gate structure and the word line gate structure after the word line gate structure is formed.

Compared with conventional technologies, embodiments of the present disclosure have following beneficial effects.

In the memory according to embodiments of the present disclosure, the control gate structure on the floating gate structure is added, and the control gate structure is in contact with the word line gate structure. Thus, the word line gate structure can form a coupling effect with the floating gate structure through the control gate structure, so as to improve a coupling coefficient between the floating gate structure and the word line gate structure, which increases a coupling voltage of the floating gate structure during programming, is beneficial to attract more hot electrons into the floating gate structure, and improves a programming efficiency and the formed memory's performance.

In the method for forming the memory according to embodiments of the present disclosure, the control gate structure is formed on the surface of the floating gate material film in the floating gate region, the word line gate structure is formed on the sidewall surface of the control gate structure and the sidewall surface of the first sidewall, and the word line gate structure is in contact with a part of the control gate structure. Thus, the word line gate structure can form a coupling effect with the floating gate structure through the control gate structure, so as to improve a coupling coefficient between the floating gate structure and the word line gate structure, which increases a coupling voltage of the floating gate structure during programming, is beneficial to attract more hot electrons into the floating gate structure and improves a programming efficiency and the formed memory's performance.

### BRIEF DESCRIPTION OF THE DRAWINGS

FIG. 1 schematically illustrates a sectional view of a flash memory; and

FIGS. 2 to 21 schematically illustrate intermediate sectional structures of a method for forming a memory according to an embodiment of the present disclosure.

### DETAILED DESCRIPTION

As mentioned in the background, there is a need for improving flash memory performance.

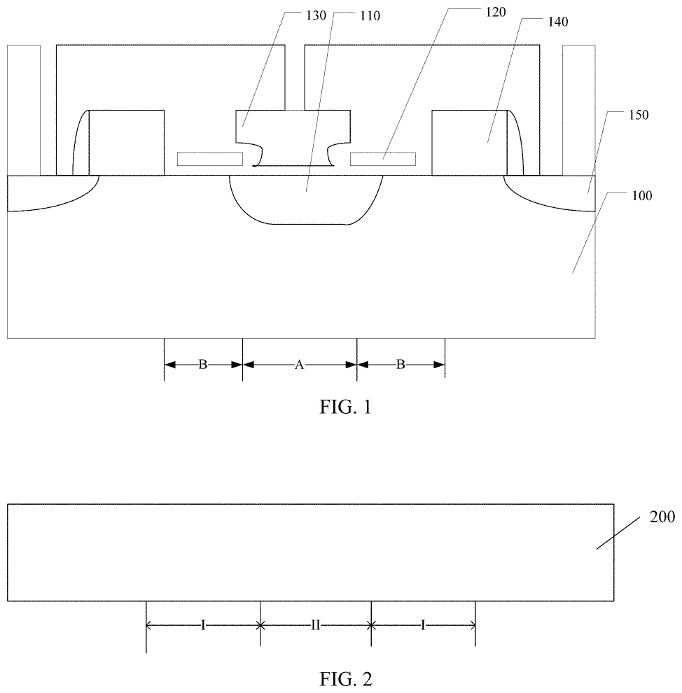

FIG. 1 schematically illustrates a sectional view of a flash memory.

Referring to FIG. 1, the flash memory includes a semiconductor substrate 100. The semiconductor substrate 100 includes an erase region A and a floating gate region B, wherein the floating gate area B is adjacent to the erase region A and both sides of the erase region A are disposed with the erase region B. An erase gate structure 130 is disposed on the erase region A of the semiconductor substrate 100. Floating gate structures 120 are respectively disposed on floating gate regions B of the semiconductor substrate 100. A word line structure 140 is disposed at one side of one floating gate structure 120, wherein the floating gate structure 120 is disposed between the erase gate structure 130 and the word line structure 140. A source 110 is disposed in the erase region A of the semiconductor substrate 100, and a bit line structure 150 is disposed in the semiconductor substrate 100, wherein the bit line structure 150 is disposed between word line structures 140 of adjacent flash memories.

In order to increase a coupling voltage between the source 110 and the floating gate structure 120 when programming, one method is to increase a coupling area between the floating gate structure 120 and the source 110, so as to increase a coupling rate between the floating gate structure 120 and the source 110. In programming, a high coupling voltage is generated on the floating gate structure 120 due to the high coupling rate, and more hot electrons are attracted to the floating gate structure 120 in programming of the floating gate structure 120.

In the structure of the above flash memory, a floating gate channel area accounts for about a half of the size of the floating gate structure 120, while the floating gate structure 120 above the source 110 is used for voltage coupling. In order to increase a voltage applied on the floating gate structure 120 when programming, it is necessary to increase an overlapping area between the source 110 and the floating gate structure 120, which in turn leads to a large size of the whole flash memory, and does not meet the trend of miniaturization of semiconductor devices.

Thus, an embodiment of the present disclosure provides a method for forming a memory. The method includes: forming a floating gate material film on an erase region and a floating gate region; forming a control gate structure on a surface of the floating gate material film on the floating gate region and exposing the floating gate material film on the erase region; forming a word line gate structure on a sidewall surface of the control gate structure and a sidewall surface of the first sidewall, wherein the word line gate structure is in contact a part of the control gate structure, thus the word line gate structure can have a coupling effect with the floating gate structure through the control gate structure, which is beneficial to improve the performance of the memory.

In order to make above purposes, features and effects of the present disclosure more obvious and understandable, specific embodiments of the present disclosure will be described in detail below in combination with the attached drawings.

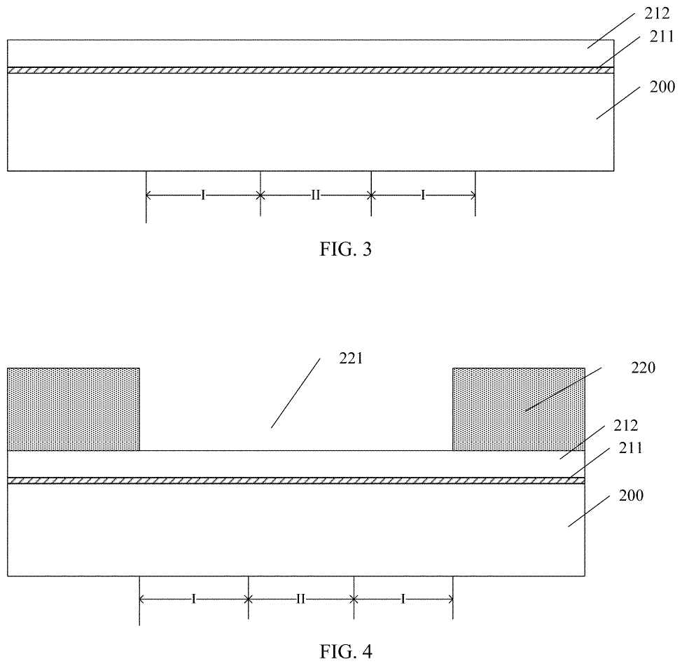

FIGS. 2 to 21 schematically illustrate intermediate sectional structures of the method for forming a memory according to an embodiment of the present disclosure.

Referring to FIG. 2, a substrate 200 is provided. The substrate 200 includes an erase region II and a floating gate region I. The floating gate region I is adjacent to the erase region II, and both sides of the erase region II is provided with the floating gate region I.

In some embodiments, the substrate 200 is made of a material including silicon; in other embodiments, the material of the substrate may also be germanium, silicon germanium, silicon carbide, gallium arsenide, or indium gallium; and in other embodiments, the substrate may also be a silicon substrate on an insulator or a germanium substrate on an insulator.

Referring to FIG. 3, a floating gate material film is formed on the erase region II and the floating gate region I.

The floating gate material film provides a material for a floating gate structure formed subsequently.

In some embodiment, the floating gate material film is also disposed on a surface of the substrate 200 on both sides of the erase region II and the floating gate region I.

The method for forming the floating gate material film includes: forming a floating gate dielectric material film 211 on the surface of the substrate 200; and forming a floating gate electrode material film 212 on a surface of the floating gate dielectric material film 211.

It should be noted that a part of the floating gate dielectric material film 211 is subsequently used to form a word line gate structure.

The floating gate dielectric material film 211 is made of a material selected from a group consisting of silicon oxide, silicon nitride, silicon carbonitride, silicon boronnitride, silicon oxycarbonitride and silicon oxynitride. In some embodiments, the floating gate dielectric material film 211 is made of silicon oxide.

The floating gate electrode material film 212 is made of polysilicon.

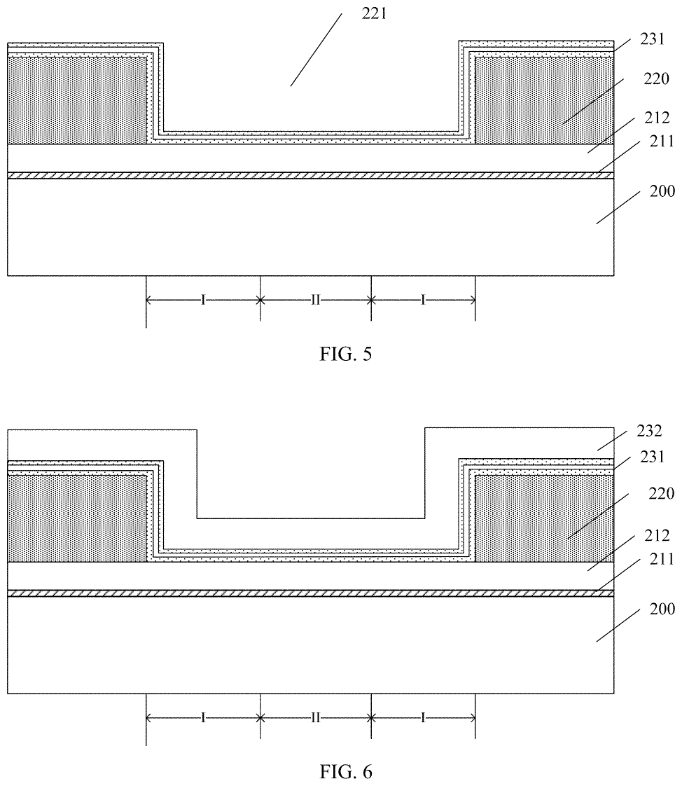

Referring to FIG. 4, a mask layer 220 is formed on the surface of the floating gate material film, the mask layer 220 has a mask opening 221, and the surface of the floating gate material film on the erase region II and the floating gate region I is exposed through the mask opening 221.

The mask layer 220 is used to define sizes and positions of subsequent control gate structure, floating gate structure and word line gate structure.

Forming the mask layer 220 and the mask opening 221 includes: forming a mask material layer (not shown in the figure) on the surface of the floating gate material film; forming a patterned layer (not shown in the figure) on a surface of the mask material layer, wherein the surface of the mask material layer on the erase region II and the floating gate region I is exposed from the patterned layer; and etching the mask material layer with the patterned layer as a mask to expose the floating gate material film so as to form the mask layer 220 and the mask opening 221.

In some embodiments, the mask layer 220 is made of silicon nitride.

Next, a control gate structure is formed on the surface of the floating gate material film on the floating gate region I to expose the floating gate material film on the erase region II. For the specific process of forming the control gate structure, please refer to FIG. 5 to FIG. 10.

Referring to FIG. 5, a control gate dielectric material film 231 is formed on a bottom surface and a sidewall surface of the mask opening 221 and a top surface of the mask layer 220.

The control gate dielectric material film 231 provides a material for a control gate dielectric layer that subsequently forms the control gate structure.

The control gate dielectric material film 231 includes an oxide material film, a nitride material film on a surface of the oxide material film, and an oxide material film on a surface of the nitride material film.

When the control gate dielectric material film has an O—N—O multi-layer structure, the subsequently formed control gate dielectric layer has a multi-layer structure correspondingly, so that it can fully isolate the control gate structure from the floating gate structure.

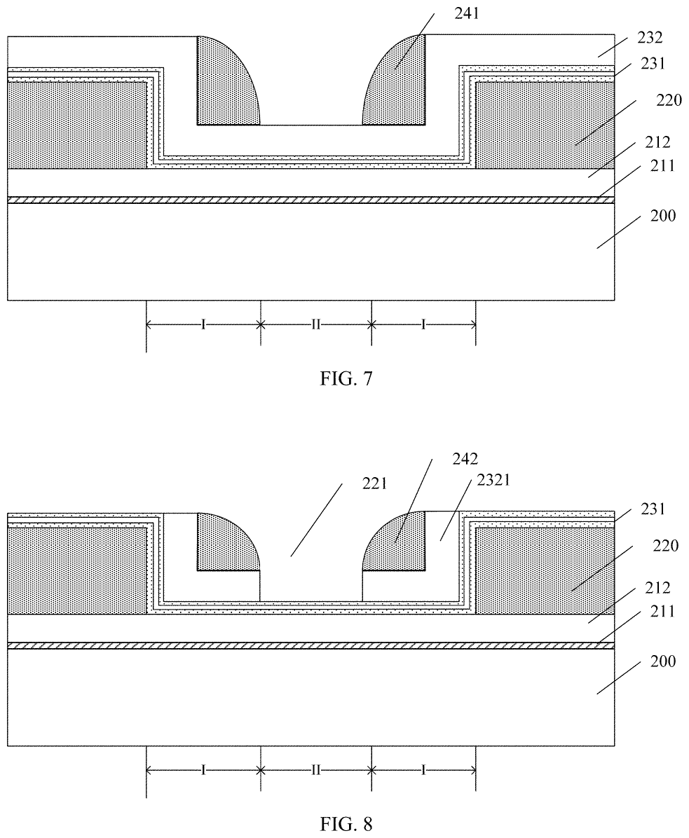

Referring to FIG. 6, a control gate electrode material film 232 is formed on a surface of the control gate dielectric material film 231.

The control gate electrode material film 232 provides a material for a control gate electrode layer that subsequently forms the control gate structure.

The control gate electrode material film 232 may be made of polysilicon.

Referring to FIG. 7, a second sidewall material film 241 is formed on a sidewall surface of the control gate electrode material film 232.

The second sidewall material film 241 provides a material for a second sidewall formed subsequently.

Forming the second sidewall material film 241 includes: forming an initial second sidewall material film 241 on a surface of the control gate material film 232; and etching back the initial second sidewall material film 241 to expose a top surface of the control gate material film 232 so as to form the second sidewall material film 241.

The second sidewall material film 241 and the mask layer 220 may be made of different materials. In some embodiments, the second sidewall material film 241 may be made of silicon oxide.

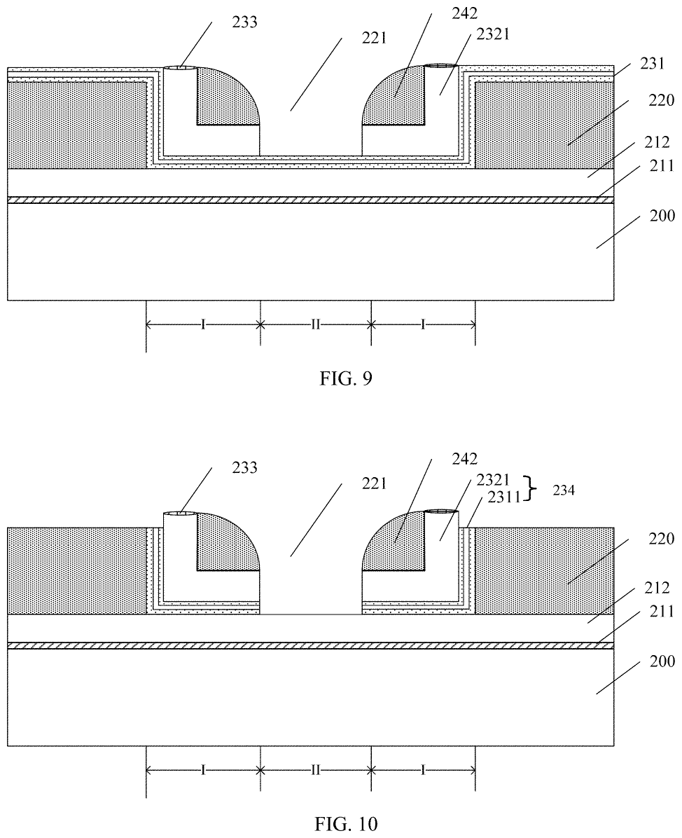

Referring to FIG. 8, the second sidewall material film 241 and the control gate electrode material film 232 are etched until the control gate dielectric material film 231 is exposed, so that the second sidewall material film 241 forms the second side wall 242, and the control gate electrode material film 232 forms a control gate electrode layer 2321.

The control gate electrode layer 2321 is used to constitute the control gate structure.

On the one hand, the second sidewall 242 can electrically isolate the control gate electrode layer 2321; on the other hand, the second sidewall 242 can protect the surface of the control gate layer 2321 and reduce influences of subsequent process.

The process for etching the second sidewall material film 241 and the control gate material film 232 may be a dry etching process.

Referring to FIG. 9, a first protective layer 233 is formed on exposed top surface of the control gate electrode layer 2321.

The first protective layer 233 may protect the top surface of the control gate electrode layer 2321, thereby reducing the influence of the subsequent process on the control gate electrode layer 2321.

In some embodiments, the first protective layer 233 may be made of silicon oxide, and the process for forming the first protective layer 233 may be a thermal oxidation process.

In other embodiments, the process for forming the first protective layer may also be a physical vapor deposition process or a chemical vapor deposition process.

Referring to FIG. 10, the control gate dielectric material film 231 is etched until the surface of the floating gate material film and the top surface of the mask layer 220 are exposed, so that a control gate dielectric layer 2311 is formed on the sidewall surface of the mask layer 220 and on a part of the bottom surface of the mask opening 221.

Specifically, in some embodiments, the control gate dielectric material film 231 is etched using the first protective layer 233 and the second sidewall 242 as a mask to form the control gate dielectric layer 2311, and the control gate dielectric layer 2311 and the control gate electrode layer 2321 constitute the control gate structure 234.

The control gate dielectric layer 2311 includes an oxide layer, a nitride layer on a surface of the oxide layer, and an oxide layer on a surface of the nitride layer.

The control gate dielectric layer 2311 has a multi-layer structure, which can fully isolate the control gate structure 234 from the floating gate structure formed subsequently.

Next, the erase gate structure is formed on the erase region II.

In some embodiments, the method for forming the memory further includes:
forming a third sidewall on a surface of the control gate structure 234 and a surface of the second side wall 242 after the control gate structure 234 is formed, and before the erase gate structure is subsequently formed.

In some embodiments, the method for forming the memory further includes: forming a source region in the erase region II on the substrate 200 after the control gate structure 234 is formed, and before the erase gate structure is subsequently formed.

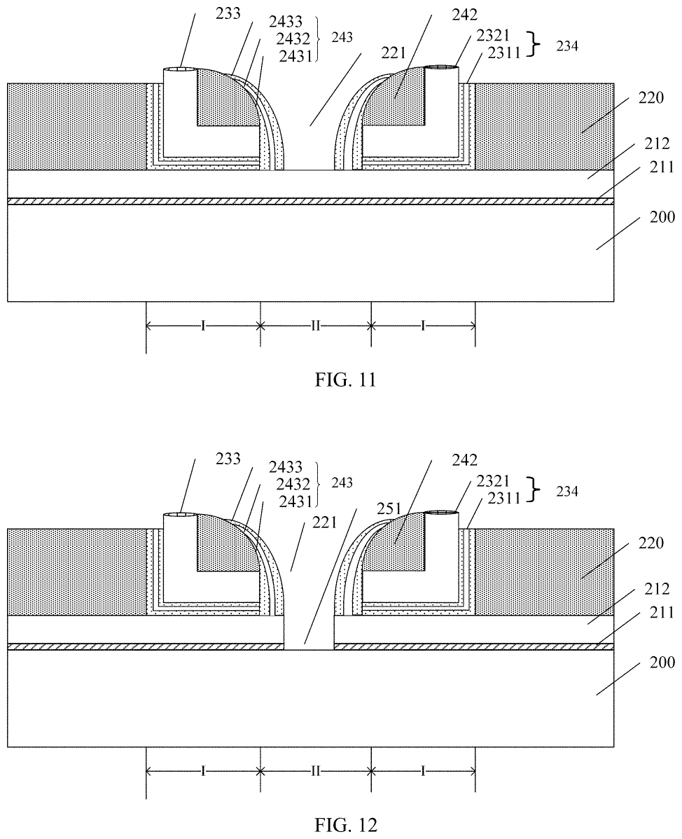

FIGS. 11 to 15 show the process of forming the third sidewall, the source region, and the erase gate structure.

Referring to FIG. 11, the third sidewall 243 is formed on the surface of the control gate structure 234 and on the surface of the second sidewall 242 in the mask opening 221.

The method for forming the third sidewall 243 includes: forming a third sidewall material film (not shown in the figure) on the sidewall surface of the control gate structure 234, on the surface of the second sidewall 242 and on the surface of the mask layer 220 in the mask opening 221; and etching the third sidewall material film to expose top surfaces of the floating gate material film, the control gate structure 234, the second sidewall 242 and the mask layer 220 so as to form the third sidewall 243.

Specifically, the surface of the second sidewall 242, the first protective layer 233 on a top surface of the control gate structure 234, and the top surface of the mask layer 220 are exposed through the third sidewall 243.

The third sidewall 243 includes: a first insulation layer 2431 on the sidewall surface of the control gate structure 234 and on the sidewall surface of the second sidewall 242, a second insulation layer 2432 on a surface of the first insulation layer 2431, and a third insulation layer 2433 on a surface of the second insulation layer 2432.

The first insulation layer 2431 is an oxide layer. In this embodiment, the first insulating layer 2431 may be made of silicon oxide.

The second insulation layer 2432 is a nitride layer. In this embodiment, the second insulating layer 2432 may be made of silicon nitride.

The third insulation layer 2433 is an oxide layer. In this embodiment, the third insulating layer 2433 may be made of silicon oxide.

The third sidewall 243 has a multi-layer structure, which is beneficial to improve the isolation effect between the control gate structure 234 and the erase gate structure 272 formed subsequently.

Referring to FIG. 12, the floating gate material film is etched using the mask layer 220, the control gate structure 234 and the second sidewall 242 as a mask until the surface of the substrate 200 is exposed, so that a floating gate opening 251 through which a surface of the erase region II is exposed is formed in the floating gate material film.

Specifically, in some embodiments, the mask layer 220, the control gate structure 234, the second sidewall 242 and the third sidewall 243 are used as the mask to etch the floating gate material film until the surface of the substrate 200 is exposed so as to form the floating gate opening 251.

Referring to FIG. 13, an ion implantation process is performed on the substrate 200 exposed at a bottom of the floating gate opening 251, so that a source region 261 is formed on the substrate 200 in the erase region II.

In some embodiments, the method for forming the memory further includes: removing the third insulation layer 2433 in the third sidewall 243 to expose a part of the surface of the floating gate material film after the floating gate opening 251 is formed.

By removing the third insulation layer 2433, a part of a top surface of the formed floating gate structure may be exposed, and the top of the floating gate structure has a protruding tip. In the subsequent erasing process between the floating gate structure and the subsequently formed erase gate structure, the tip is beneficial to the electronic discharge stored in the floating gate structure, thereby improving the erasing efficiency.

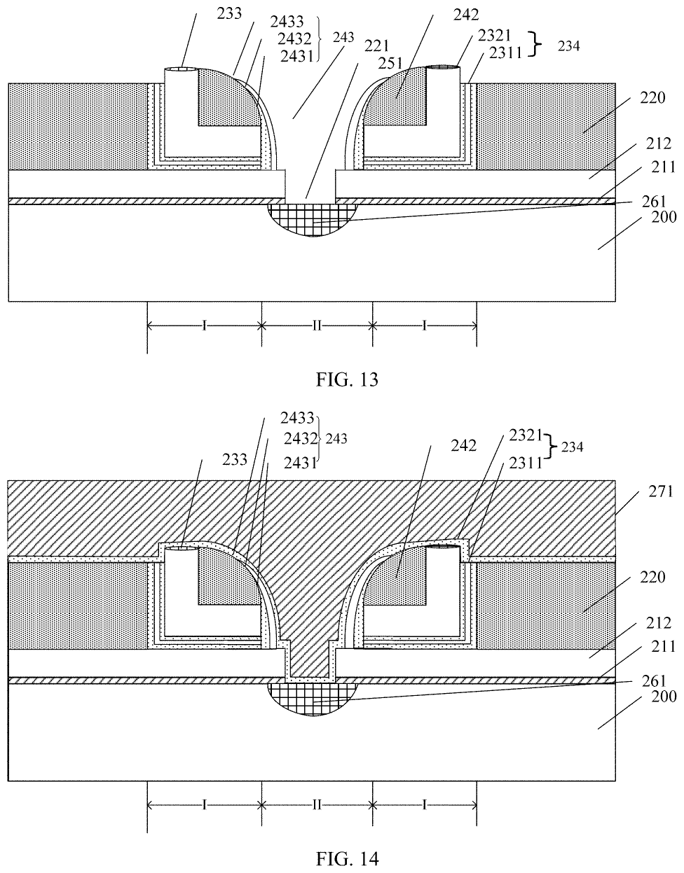

Referring to FIG. 14, an erase gate material film 271 is formed in the mask opening 221 and the floating gate opening 251, and on the surface of the second sidewall 242, the surface of the control gate structure 234 and the surface of the mask layer 220.

The erase gate material film 271 provides material for an erase gate structure formed subsequently.

Specifically, the method for forming the erase gate material film 271 includes: forming an erase gate dielectric material film (not shown in the figure) on the surface of the second sidewall 242, on a surface of the first protective layer 233 and on the surface of the mask layer 220; and forming an erase gate electrode material film (not shown in the figure) on a surface of the erase gate dielectric material film. The mask opening 221 and the floating gate opening 251 are filled with the erase gate electrode material film.

The erase gate dielectric material film is made of a material selected from a group consisting of silicon oxide, silicon nitride, silicon carbonitride, silicon boronnitride, silicon oxycarbonitride and silicon oxynitride. In some embodiments, the erase gate dielectric material film is made of silicon oxide.

The erase gate electrode material film may be made of polysilicon.

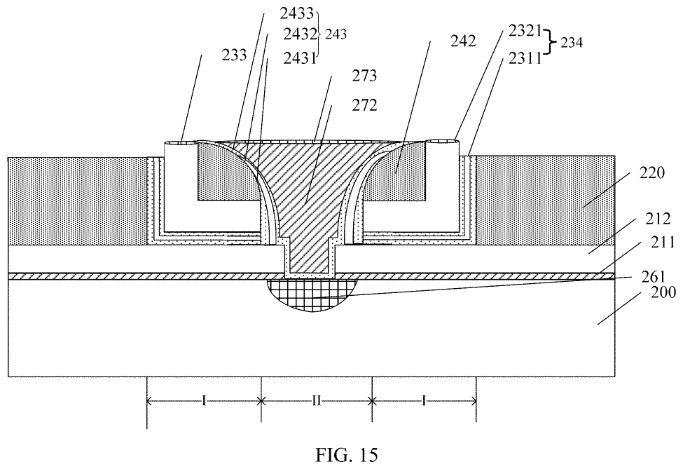

Referring to FIG. 15, the erase gate material film 271 is planarized until the surface of the second sidewall 242, the surface of the control gate structure 234 and the surface of the mask layer 220 are exposed so as to form the erase gate structure 272, and the erase gate structure 272 is disposed between adjacent control gate structures 234.

The process for planarizing the erase gate material film 271 includes a chemical mechanic planarization process.

In some embodiments, the method for forming the memory further includes: forming a second protective layer 273 on the surface of the erase gate structure 272.

The second protective layer 273 may protect the top surface of the erase gate structure 272, thereby reducing the influence of the subsequent process on the erase gate structure 272.

In some embodiments, the second protective layer 273 may be made of silicon oxide, and the second protective layer 273 may be formed by a thermal oxidation process.

In other embodiments, the second protective layer may also be formed by a physical vapor deposition process or a chemical vapor deposition process.

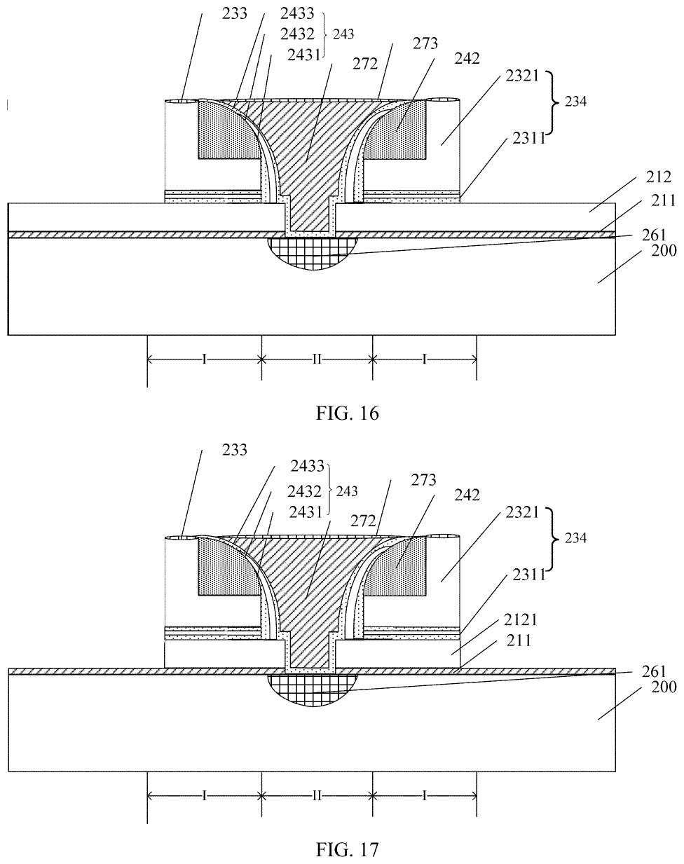

After the erase gate structure 273 is formed, the floating gate material film is etched until the surface of the substrate 200 is exposed, so that the floating gate structure is formed on the floating gate region I. The floating gate structure has a sidewall with a first side and a second side opposite to each other, and the first side is adjacent to the floating gate region. For the specific process of forming the floating gate structure, please refer to FIGS. 16 to 17.

Referring to FIG. 16, the mask layer 220 and the control gate dielectric layer 2311 on the sidewall surface of the mask layer 220 are removed to expose the surface of the floating gate material film.

The process of removing the mask layer 220 and the control gate dielectric layer 2311 on the sidewall surface of the mask layer 220 includes one or a combination of a wet etching process and a dry etching process.

Referring to FIG. 17, using the second sidewall 242, the control gate structure 234, and the erase gate structure 272 as a mask, the floating gate material film 212 is etched until the surface of the floating gate dielectric material film 211 is exposed, so that the floating gate material film 212 forms a floating gate electrode layer 2121, and the floating gate structure (not shown in the figure) is formed on the floating gate region I.

It should be noted that the floating gate structure is composed of the floating gate electrode layer 2121 and the floating gate dielectric material film 211 at a bottom of the floating gate electrode layer 2121, and the floating gate dielectric material film 211 at the bottom of the floating gate electrode layer 2121 serves as the floating gate dielectric layer.

The sidewall of the floating gate structure includes the first side (not shown in the figure) and the second side (not shown in the figure) opposite to each other, and the first side is adjacent to the floating gate region I.

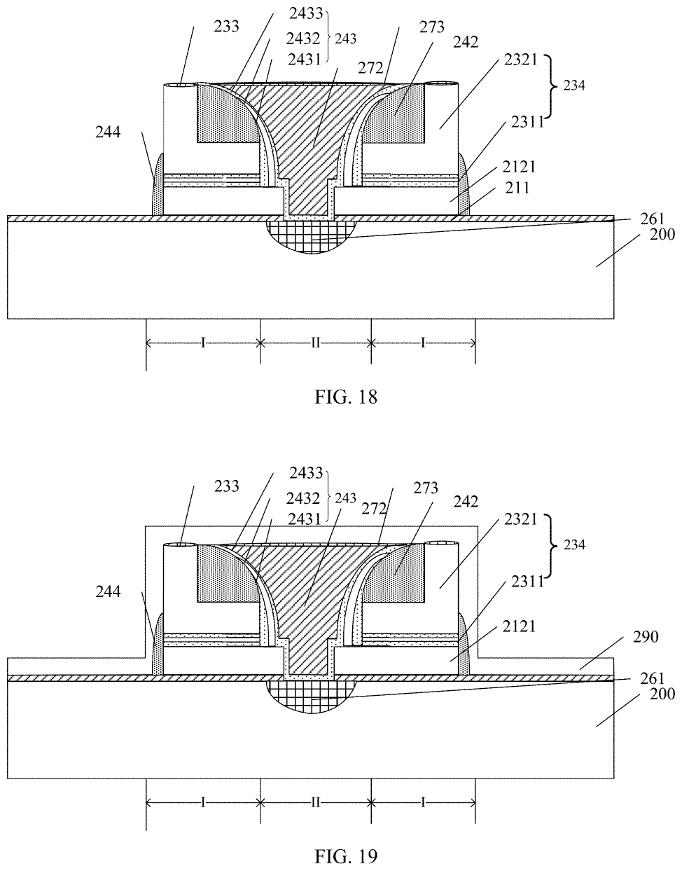

Referring to FIG. 18, a sidewall surface of the first side of the floating gate structure 281 forms the first sidewall 244.

The first sidewall 244 can electrically isolate the floating gate structure from the word line gate structure formed subsequently.

The method for forming the first sidewall 244 includes: forming a first sidewall material film (not shown in the figure) on the surfaces of the control gate structure 234, the floating gate structure and the substrate 200; and etching the first sidewall material film to expose the surface of the substrate 200 and the surface of the control gate structure 234 so that the first sidewall 244 is formed on the sidewall surface of the floating gate structure.

In some embodiments, the first sidewall 244 is also disposed on a sidewall surface of the control gate dielectric layer 2311 and on a part of a sidewall surface of the control gate electrode layer 2321.

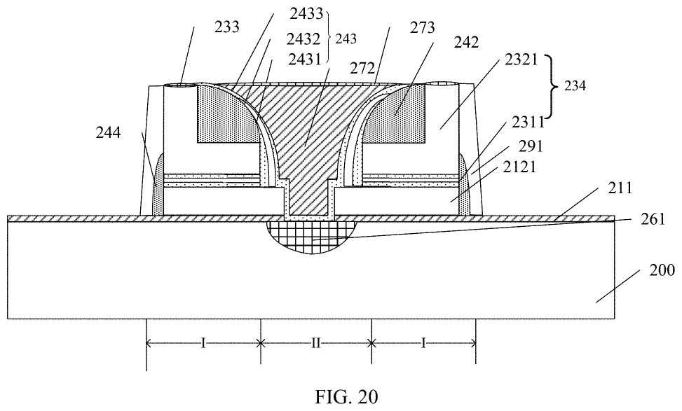

Next, the word line gate structure is formed on the sidewall surfaces of the control gate structure 234 and the first sidewall 244, and the word line gate structure is in contact with a part of the control gate structure 233. For the specific forming process of the word line gate structure, please refer to FIGS. 19 to 20.

Referring to FIG. 19, a word line gate material film 290 is formed on the surface of the substrate 200, on the surface of the first sidewall 244, and on the surface of the control gate structure 234.

The word line gate material film 290 is used to subsequently form a word line gate electrode layer of the word line gate structure.

In some embodiments, the word line gate material film 290 is also disposed on surfaces of the first protective layer 233, the second sidewall 242 and the second protective layer 273.

The word line gate material film 290 may be made of polysilicon or metal. In this embodiment, the word line gate material film 290 is made of polysilicon.

Since the sidewall surface of the control gate structure 234 is exposed through the first sidewall 244, the word line gate material film 290 may be in contact with the control gate structure 234, so that the word line gate structure formed by subsequently etching the word line gate material film 290 may be in contact with the control gate structure 234.

Referring to FIG. 20, the word line gate material film 290 is etched back until the surface of the substrate 200 is exposed, so that the word line gate material film 290 forms a word line gate electrode layer 291 so as to form the word line gate structure (not shown in the figure).

Specifically, in some embodiments, the word line gate material film 290 is etched back until the surfaces of the floating gate dielectric material film 211, the first protective layer 233, the second sidewall 242, and the second protective layer 273 are exposed.

It should be noted that the word line gate structure is composed of the word line gate electrode layer 291 and the floating gate dielectric material film 211 at a bottom of the word line gate electrode layer 291. The floating gate dielectric material film 211 at the bottom of the word line gate electrode layer 291 serves as the word line gate dielectric layer of the word line gate structure.

The word line gate structure is disposed on the sidewall surfaces of the control gate structure 234 and the first sidewall 244, and the word line gate structure is in contact with a part of the control gate structure 234.

By forming the control gate structure 234 on the surface of the floating gate material film on the floating gate region I, forming the word line gate structure on the sidewall surfaces of the control gate structure 234 and the first sidewall 244, and configuring the word line gate structure to be in contact with a part of the control gate structure 234, the word line gate structure can form a coupling effect with the floating gate structure through the control gate structure 234, so as to improve a coupling coefficient between the floating gate structure and the word line gate structure, which increases a coupling voltage of the floating gate structure during programming, is beneficial to attract more hot electrons into the floating gate structure and improves a programming efficiency and the formed memory's performance.

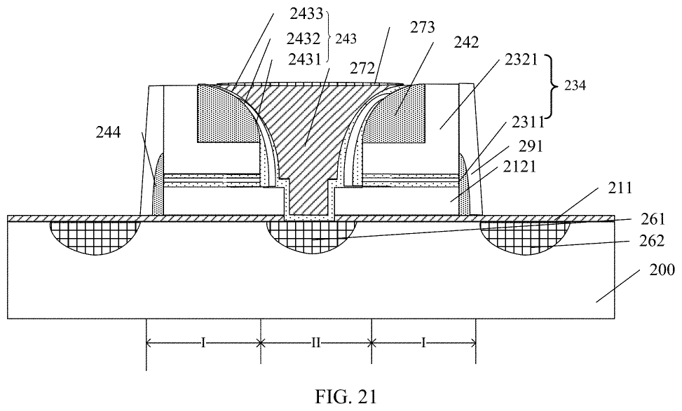

Referring to FIG. 21, after the word line gate structure is formed, a drain region 262 is formed in the substrate 200 on both sides of the control gate structure 234 and the word line gate structure.

The method for forming the drain region 262 includes: performing an ion implantation process on the substrate 200 with the control gate structure 234, the word line gate structure, the second sidewall 242 and the erase gate structure 272 as a mask.

In some embodiments, before the ion implantation process, the method further includes: removing the floating gate dielectric material film 211 on the surface of the substrate 200 on both sides of the control gate structure 234, the word line gate structure, the second sidewall 242 and the erase gate structure 272 to expose the surface of the substrate 200.

In some embodiments, after the ion implantation process, the method further includes: removing the first protective layer 233 on the top surface of the control gate structure 234.

Correspondingly, another embodiment of the present disclosure also provides a memory formed by the above method. Referring to FIG. 21, the memory includes: a substrate 200 including an erase region II and a floating gate region I, wherein the floating gate region I is adjacent to the erase region II, and both sides of the erase region I is disposed with the floating gate region II; a floating gate structure (not shown in the figure) on the floating gate region; a control gate structure 234 on the floating gate structure; a word line gate structure (not shown in the figure) on the substrate 200 on both sides of the erase region II and the floating gate region I, wherein the word line gate structure is in contact with a part of the control gate structure 234, and a first sidewall 244 is disposed between the floating gate structure and the word line gate structure.

In the memory, the control gate structure 234 on the floating gate structure is added, and the control gate structure 234 is in contact with the word line gate structure. Thus, the word line gate structure can form a coupling effect with the floating gate structure through the control gate structure 234, so as to improve a coupling coefficient between the floating gate structure and the word line gate structure, which increases a coupling voltage of the floating gate structure during programming, is beneficial to attract more hot electrons into the floating gate structure, and improves a programming efficiency and the formed memory's performance.

The specific embodiments will be described in detail below with reference to the drawings.

The memory further includes an erase gate structure 272 disposed on the erase region II, and the erase gate structure 272 is disposed between adjacent floating gate structures.

The memory further includes a source region 261 disposed in the erase region II, and a drain region 262 disposed in the substrate 200 on both sides of the floating gate structure, the control gate structure 234, and the word line gate structure.

The memory further includes a second sidewall 242 disposed on the surface of the control gate structure 234.

The memory further includes a third sidewall 243 disposed on the sidewall surface of the second sidewall 242 and on the sidewall surface of the control gate structure 234, and a part of the top surface of the floating gate structure is exposed from the third sidewall 243 and the control gate structure 234.

The control gate structure 234 includes a control gate dielectric layer 2311 and a control gate electrode layer 2312 on a surface of the control gate dielectric layer 2311. The control gate dielectric layer 2311 includes an oxide layer (not shown in the figure), a nitride layer (not shown in the figure) on a surface of the oxide layer and an oxide layer (not shown in the figure) on a surface of the nitride layer, and the control gate electrode layer is made of polysilicon.

The floating gate structure includes a floating gate dielectric layer and a floating gate electrode layer 2121 on a surface of the floating gate dielectric layer. The floating gate dielectric layer may be made of silicon oxide, and the floating gate electrode layer 2121 may be made of polysilicon.

It should be noted that the floating gate dielectric material film 211 at the bottom of the floating gate electrode layer 2121 serves as the floating gate dielectric layer of the floating gate structure, and the floating gate dielectric layer is disposed on the floating gate region I.

The word line gate structure includes a word line gate dielectric layer and a word line gate electrode layer 291 on a surface of the word line gate dielectric layer. The word line gate dielectric layer may be made of silicon oxide, and the word line gate electrode layer 291 may be made of polysilicon.

It should be noted that the floating gate dielectric material film 211 at the bottom of the word line gate electrode layer 291 serves as the word line gate dielectric layer of the word line gate structure.

Although the present disclosure has been disclosed above, the present disclosure is not limited thereto. Any changes and modifications may be made by those skilled in the art without departing from the spirit and scope of the present disclosure, and the scope of the present disclosure should be determined by the appended claims.

1. A memory, comprising:
a substrate comprising an erase region and a floating gate region, wherein the floating gate region is adjacent to the erase region, and both sides of the erase region are disposed with the floating gate region;
a floating gate structure disposed on the floating gate region;
a control gate structure disposed on the floating gate structure; and
a word line gate structure disposed on the substrate on both sides of the erase region and the floating gate region, wherein the word line gate structure is in contact with a part of the control gate structure, and a first sidewall is disposed between the floating gate structure and the word line gate structure.

2. The memory according to claim 1, further comprising:
an erase gate structure disposed on the erase region, wherein the erase gate structure is disposed between adjacent floating gate structures.

3. The memory according to claim 1, further comprising:
a source region disposed in the erase region; and
a drain region disposed in the substrate on both sides of the floating gate structure, the control gate structure and the word line gate structure.

4. The memory according to claim 1, further comprising:
a second sidewall disposed on a surface of the control gate structure.

5. The memory according to claim 4, further comprising:
a third sidewall disposed on a sidewall surface of the second sidewall and a sidewall surface of the control gate structure, and a part of a top surface of the floating gate structure is exposed through the third sidewall and the control gate structure.

6. The memory according to claim 1, wherein the control gate structure comprises a control gate dielectric layer and a control gate electrode layer on a surface of the control gate dielectric layer, the control gate dielectric layer comprises an oxide layer, a nitride layer on the oxide layer and an oxide layer on the nitride layer, and the control gate electrode layer is made of a material comprising polysilicon.

7. The memory according to claim 1, wherein the floating gate structure comprises a floating gate dielectric layer and a floating gate electrode layer on a surface of the floating gate dielectric layer, the floating gate dielectric layer is made of a material comprising silicon oxide, and the floating gate electrode layer is made of a material comprising polysilicon.

8. A method for forming a memory, comprising:
providing a substrate comprising an erase region and a floating gate region, wherein the floating gate region is adjacent to the erase region, and both sides of the erase region is disposed with the floating gate region;
forming a floating gate material film in the erase region and in the floating gate region;
forming a control gate structure on a surface of the floating gate material film in the floating gate region and exposing the floating gate material film in the erase region;
etching the floating gate material film to expose a surface of the substrate so as to form a floating gate structure in the floating gate region, wherein the floating gate structure comprises a sidewall having a first side and a second side opposite to each other, and the first side is adjacent to the floating gate region;
forming a first sidewall on a sidewall surface of the first side of the floating gate structure; and
forming a word line gate structure on a sidewall surface of the control gate structure and a sidewall surface of the first sidewall, wherein the word line gate structure is in contact with a part of the control gate structure.

9. The method according to claim 8, further comprising:
forming a mask layer on the surface of the floating gate material film after the floating gate material film is formed and before the control gate structure is formed, wherein a mask opening is disposed in the mask layer, and the surface of the floating gate material film in the erase region and in the floating gate region is exposed through the mask opening.

10. The method according to claim 9, wherein forming the control gate structure comprises:
forming a control gate dielectric material film on a bottom surface and a sidewall surface of the mask opening and a top surface of the mask layer;
forming a control gate electrode material film on a surface of the control gate dielectric material film; and
etching the control gate dielectric film and the control gate electrode material film to expose the floating gate material film so as to form the control gate structure in the floating gate region.

11. The method according to claim 10, further comprising:
forming a second sidewall material film on a sidewall surface of the control gate electrode material film after the control gate electrode material film is formed and before the control gate dielectric material film and the control gate electrode material film are etched;
etching the second sidewall material film and the control gate electrode material film to expose the control gate dielectric material film so that the second sidewall material film forms the second sidewall and the control gate material film forms a control gate electrode layer; and
etching the control gate dielectric material film after the control gate electrode layer and the second sidewall are formed to expose the floating gate material film and the top surface of the mask layer so as to form a control gate dielectric layer on a sidewall surface of the mask layer and on a part of the bottom surface of the mask opening.

12. The method according to claim 11, further comprising:
forming a first protective layer on an exposed top surface of the control gate electrode layer after the second sidewall and the control gate electrode layer are formed, and before the control gate dielectric material film is etched; and
etching the control gate dielectric material film with the first protective layer and the second sidewall as a mask to form the control gate dielectric material film, wherein the control gate dielectric layer and the control gate electrode layer constitute the control gate structure.

13. The method according to claim 11, further comprising:
forming an erase gate structure on the erase region after the control gate structure is formed and before the word line gate structure is formed;
wherein forming the erase gate structure comprises:
etching the floating gate material film with the mask layer, the control gate structure and the second sidewall as a mask to expose the substrate so as to form a floating gate opening exposing a surface of the erase region in the floating gate material film;
forming an erase gate material film in the mask opening and the floating gate opening, and on a surface of the second sidewall, on a surface of the control gate structure and on a surface of the mask layer; and
planarizing the erase gate material film to expose the surface of the second sidewall, the surface of the control gate structure and the surface of the mask layer to form the erase gate structure, wherein the erase gate structure is disposed between adjacent control gate structures.

14. The method according to claim 13, further comprising:
forming a second protective layer on a surface of the erase gate structure after the erase gate structure is formed and before the floating gate structure is formed.

15. The method according to claim 13, further comprising:
forming a third sidewall on the surface of the control gate structure and on the surface of the second sidewall in the mask opening after the control gate structure and the second sidewall are formed and before the floating gate opening is formed; and
etching the floating gate material film with the mask layer, the control gate structure, the second sidewall and the third sidewall as a mask to expose the substrate so as to form the floating gate opening;
wherein forming the third sidewall comprises:
forming a third sidewall material film on a sidewall surface of the control gate structure, on the surface of the second sidewall and on the surface of the mask layer in the mask opening; and
etching the third sidewall material film to expose the floating gate material film, the control gate structure, the second sidewall and the top surface of the mask layer so as to form the third sidewall.

16. The method according to claim 15, wherein the third sidewall comprises a first insulation layer on a sidewall surface of the control gate structure and on a sidewall surface of the second sidewall, a second insulation layer on a surface of the first insulation layer, and a third insulation layer on a surface of the second insulation layer;
wherein the method for forming the memory further comprises:
removing the third insulation layer in the third sidewall to expose a part of the surface of the floating gate material film after the floating gate opening is formed; and
forming the erase gate structure in the floating gate opening and the mask opening after the third insulation layer is removed.

17. The method according to claim 15, further comprising:
performing an ion implantation process in the substrate exposed at a bottom of the floating gate opening to form a source region in the substrate in the erase region after the third sidewall is formed and before the erase gate structure is formed.

18. The method according to claim 13, wherein forming the floating gate material film comprises:
forming a floating gate dielectric material film on the surface of the substrate; and
forming a floating gate electrode material film on a surface of the floating gate dielectric film.

19. The method according to claim 18, wherein forming the floating gate structure comprises:
removing the mask layer and the control gate dielectric layer on the sidewall surface of the mask layer to expose the floating gate material film; and
etching the floating gate material film with the second sidewall, the control gate structure and the erase gate structure as a mask to expose the surface of the floating gate dielectric material film so that the floating gate electrode material film forms a floating gate electrode layer and the floating gate structure is formed in the floating gate region.

20. The method according to claim 8, wherein forming the first sidewall comprises:
forming a first sidewall material film on a surface of the control gate structure, on a surface of the floating gate structure and on the surface of the substrate; and
etching the first sidewall material film to expose the surface of the substrate and the surface of the control gate structure so as to form the first sidewall on a sidewall surface of the floating gate structure;
wherein forming the word line gate structure comprises:
forming a word line gate material film on the surface of the substrate, on a surface of the first sidewall and on a surface of the control gate structure; and
etching back the word line gate material film to expose the surface of the substrate so as to form the word line gate structure;
wherein the method further comprises:
forming a drain region in the substrate on both sides of the control gate structure and the word line gate structure after the word line gate structure is formed.
